(19) United States
(12) Patent Application Publication
(10) Pub. No.: US 2023/0289717 A1
(43) Pub. Date: Sep. 14, 2023

(54) INVENTORY MANAGEMENT SYSTEM

(71) Applicant: HONDA MOTOR CO., LTD., Tokyo (JP)

(72) Inventor: Satoshi Matsuzawa, Minato-ku, Tokyo (JP)

(21) Appl. No.: 18/004,355

(22) PCT Filed: Jul. 10, 2020
(86) PCT No.: PCT/JP2020/027090

§ 371 Date: Jan. 5, 2023

(51) Int. Cl. G06Q 10/087; G01R 31/392

(52) U.S. Cl. CPC G06Q 10/087; G01R 31/392

(57) ABSTRACT

An inventory management system that can achieve both re-using of batteries and securing of the convenience of electric products for which the batteries are to be reused. The inventory management system for a plurality of batteries to be used in an electric taxi and an electric lawnmower includes: a deterioration degree range storage unit that stores, as a first deterioration degree range, the range of a necessary deterioration degree of a battery, which is set in association with the electric taxi; and a distribution unit that associates, with the electric lawnmower, a battery having a deterioration degree higher than the first deterioration degree range among batteries associated with the electric taxi.

### TECHNICAL FIELD

The present invention relates to an inventory management system for a plurality of batteries used in a plurality of types of electrically powered products.

### BACKGROUND ART

In JP 2009-208484 A, a technology is disclosed for calculating and displaying a degree of degradation (SOH) of batteries the performance of which undergo degradation due to repeated charging and discharging.

### SUMMARY OF THE INVENTION

Battery performance requirements vary greatly depending on the types of electrically powered products in which the batteries are used. For this reason, even if the degradation of a battery progresses, and the battery does not satisfy the performance required in order to ensure convenience with the type of electrically powered products currently in use, even in the case of such a battery, the battery may still satisfy the performance required for use with other types of electrically powered products. However, those batteries that no longer satisfy the performance required for the type of electrically powered products currently in use, are not be used again in other types of electrically powered products, but rather are sent for recycling. Further, since it is difficult for an operator to grasp the required battery performance for the other types of electrically powered products, a concern arises in that the batteries whose performance is excessive or insufficient may be used again in the other types of electrically powered products, and the residual values of such batteries may not be appropriately utilized.

The present invention has been devised in order to solve the aforementioned problems, and has the object of providing an inventory management system which is capable of realizing both the features of enabling batteries to be used again and ensuring convenience of electrically powered products for which the batteries are used again.

According to an aspect of the present invention, there is provided an inventory management system for a plurality of batteries used in a plurality of types of electrically powered products, the inventory management system including a degree of degradation range storage unit configured to store, as a first degree of degradation range, a range of a required degree of degradation required for batteries, among the plurality of batteries, that are set in association with a first type of the electrically powered products, and to store, as a second degree of degradation range, a range of a required degree of degradation required for batteries thereamong that are set in association with a second type of the electrically powered products, wherein the second degree of degradation range is set to a range in which a degree of degradation is higher than a degree of degradation of the first degree of degradation range, a degree of degradation acquisition unit configured to acquire a degree of degradation respectively of each of the plurality of batteries, a state of usage storage unit configured to store, in association with each other, the types of the electrically powered products and the batteries used by the types of the electrically powered products, and a distribution unit configured to associate, from among the batteries associated with the first type of the electrically powered products, a battery having the degree of degradation higher than the first degree of degradation range, with the second type of the electrically powered products.

According to the present invention, it is possible to realize both the features of enabling the batteries to be reused in electrically powered products and ensuring the performance of the batteries in the electrically powered products.

### BRIEF DESCRIPTION OF DRAWINGS

FIG. 1 is a schematic diagram showing a process flow when batteries are used again;

FIG. 2 is a diagram for describing a distribution of batteries in each of respective groups;

FIG. 3 is a block diagram of an inventory management system;

FIG. 4 is a table showing an example of a required SOH range stored in a degree of degradation range storage unit;

FIG. 5 is a table showing an example of the contents of battery usage states stored in a state of usage storage unit;

FIG. 6 is a table showing an example of the number of batteries belonging to each group, the required number of batteries, and an inventory quantity of the batteries, which are stored in a number storage unit;

FIG. 7 is a flow chart showing a process flow of a distribution process performed by a distribution unit;

FIG. 8 is a flow chart showing a process flow of a distribution process performed by the distribution unit;

FIG. 9 is a flow chart showing a process flow of a distribution process performed by the distribution unit;

FIG. 10 is a flow chart showing a process flow of a distribution process performed by the distribution unit;

FIG. 11 is a diagram for describing a distribution of batteries in each of the groups;

FIG. 12 is a diagram illustrating a distribution of batteries in each of the groups;

FIG. 13 is a diagram for describing a distribution of batteries in each of the groups;

FIG. 14 is a diagram for describing a distribution of batteries in each of the groups;

FIG. 15 is a diagram for describing a distribution of batteries in each of the groups;

FIG. 16 is a diagram for describing a distribution of batteries in each of the groups; and

FIG. 17 is a diagram for describing a distribution of batteries in each of the groups.

### DETAILED DESCRIPTION OF THE INVENTION

### First Embodiment

### [Reusage of Batteries in a Plurality of Types of Electrically Powered Products]

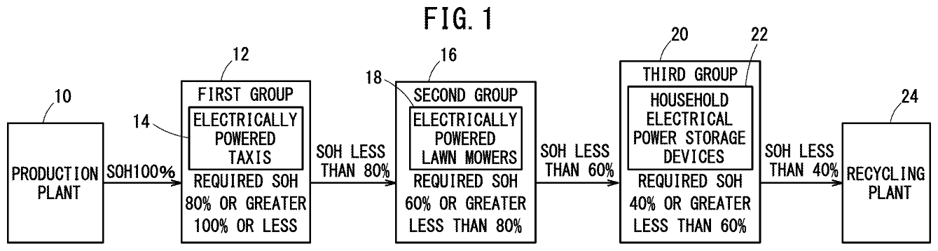

FIG. 1 is a schematic diagram showing a process flow when batteries are used again.

Batteries manufactured in a production plant 10 are sent to a first group 12. A plurality of electrically powered taxis 14 belong to the first group 12, and the batteries are used by the electrically powered taxis 14. The electrical power of the batteries is used as a powering energy for the electrically powered taxis 14. When the level of electrical power of the batteries decreases, the batteries are charged in battery stations 28, to be described later, and are used again in the electrically powered taxis 14.

Batteries whose state of health (hereinafter referred to as SOH), which is one of various indexes indicating a degree of degradation of the batteries, is less than 80% are sent from the first group 12 to a second group 16. A plurality of electrically powered lawn mowers 18 belong to the second group 16, and the batteries are used by the electrically powered lawn mowers 18. The electrical power of the batteries is used as a powering energy for the electrically powered lawn mowers 18. When the level of electrical power of the batteries decreases, the batteries are charged in charging devices 30, to be described later, and are used again in the electrically powered lawn mowers 18.

Batteries whose SOH is less than 60% are sent from the second group 16 to a third group 20. A plurality of household electrical power storage devices 22 belong to the third group 20, and the batteries are used by the household electrical power storage devices 22. The batteries are used as batteries inside the household electrical power storage devices 22. For example, the household electrical power storage devices 22 are connected to household appliances at the time of a power outage, and supply electrical power to the household appliances. When the level of electrical power of the batteries decreases, the household electrical power storage devices 22 are connected to a commercial power source, and the batteries are charged and used again.

Batteries whose SOH is less than 40% are sent from the third group 20 to a recycling plant 24, and are recycled at the recycling plant 24.

Batteries whose SOH is less than or equal to 100% and greater than or equal to 80% belong in the first group 12, batteries whose SOH is less than 80% and greater than or equal to 60% belong in the second group 16, batteries whose SOH is less than 60% and greater than or equal to 40% belong in the third group 20, and batteries whose SOH is less than 40% are to be recycled in the recycling plant 24.

This may be done in a manner so that the batteries having the number of charging times or the number of discharging times of greater than or equal to zero times and less than 750 times belong in the first group 12, batteries having the number of charging times or the number of discharging times of greater than or equal to 750 times and less than 950 times belong in the second group 16, batteries having the number of charging times or the number of discharging times of greater than or equal to 950 times and less than 1000 times belong in the third group 20, and batteries having the number of charging times or the number of discharging times of greater than or equal to 1000 times are to be recycled in the recycling plant 24.

According to the present embodiment, the degrees of degradation of the batteries are obtained based on the SOH or the number of times that the batteries are charged. The lower the SOH, the higher the degree of degradation. The greater the number of times that the batteries are charged, the higher the degree of degradation. Instead of the SOH of the battery and the number of times that the batteries are charged, the degree of degradation may be obtained based on the number of discharging times of the batteries. The greater the number of times that the batteries are discharged, the higher the degree of degradation. Moreover, it should be noted that the SOH is expressed as a percentage of the amount of electrical power (Ah) of the current battery at a time of being fully charged to the amount of electrical power (Ah) of a new battery at a time of being fully charged, wherein the SOH of the new one is taken to be 100%.

The first group 12 may be, for example, a company that operates the electrically powered taxis 14. The second group 16 may be, for example, a landscaping company that utilizes the electrically powered lawn mowers 18. The third group 20 may be a service providing company that provides a flat-rate service for the household electrical power storage devices 22.

The electrically powered taxis 14, the electrically powered lawn mowers 18, and the household electrical power storage devices 22 correspond to the electrically powered products in the present invention. The electrically powered taxis 14 correspond to a first type of the electrically powered products in the present invention, the electrically powered lawn mowers 18 correspond to a second type of the electrically powered products in the present invention, and the household electrical power storage devices 22 correspond to a third type of the electrically powered products in the present invention.

### [Configuration of Inventory Management System]

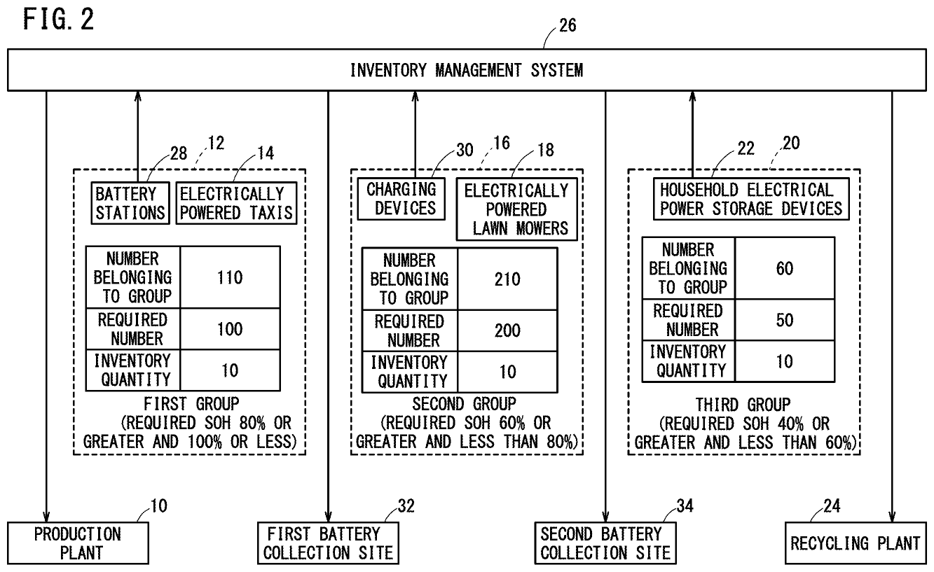

FIG. 2 is a diagram for describing a distribution of batteries in each of the first group 12, the second group 16, and the third group 20. The batteries are managed, for example, by an inventory management system 26 possessed by a battery providing company. On the basis of instructions output from the inventory management system 26, collection or delivery of the batteries is carried out by the production plant 10, a first battery collection site 32, a second battery collection site 34, and the recycling plant 24. The production plant 10, the first battery collection site 32, the second battery collection site 34, and the recycling plant 24 may be facilities operated by the battery providing company, or may be facilities operated by another type of company. The collection and the delivery of the batteries may be performed, for example, by a freight vehicle operated by a driver, or may be performed by a freight vehicle the operation of which is carried out automatically. The collection and the delivery of the batteries may be performed by the battery providing company, or may be performed by another type of delivery company.

The battery stations 28 of the first group 12, the charging devices 30 of the second group 16, and the household electrical power storage devices 22 of the third group 20 carry out management of the batteries in their respective groups. The management of the batteries in their respective groups implies grasping IDs of the batteries belonging to the respective groups, the SOHs, the number of charging times, or the number of discharging times of the batteries belonging to the respective groups, the number of batteries belonging to the respective groups, the required number of batteries required for the electrically powered products belonging to the respective groups, and an inventory quantity of the batteries belonging to the respective groups. The battery stations 28 of the first group 12, the charging devices 30 of the second group 16, and the household electrical power storage devices 22 of the third group 20 are connected to be capable of communicating with the inventory management system 26, and provide various types of information to the inventory management system 26.

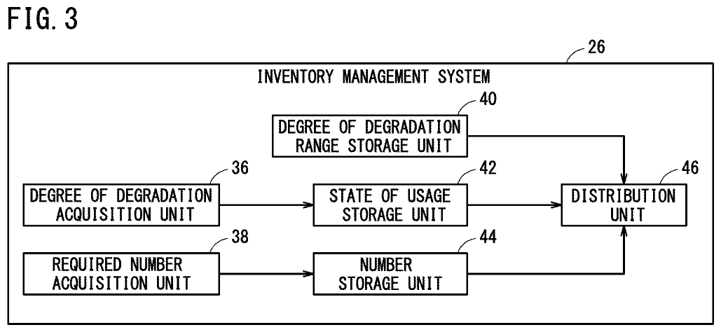

FIG. 3 is a block diagram of the inventory management system 26. The inventory management system 26 manages the number of batteries belonging to the first group 12, the number of batteries belonging to the second group 16, and the number of batteries belonging to the third group 20, and the required number and an inventory quantity of the batteries, together with managing the movement of the batteries between the first group 12, the second group 16, and the third group 20.

The inventory management system 26 includes a degree of degradation acquisition unit 36, a required number acquisition unit 38, a degree of degradation range storage unit 40, a state of usage storage unit 42, a number storage unit 44, and a distribution unit 46.

The degree of degradation acquisition unit 36 acquires the SOH, the number of charging times, or the number of discharging times of each of the batteries from the battery stations 28 of the first group 12, the charging devices 30 of the second group 16, and the household electrical power storage devices 22 of the third group 20.

The required number acquisition unit 38 acquires the required number of batteries in each of the groups from the battery stations 28 of the first group 12, the charging devices 30 of the second group 16, and the household electrical power storage devices 22 of the third group 20. The required number of batteries in each of the groups increases or decreases depending on the number of the electrically powered taxis 14 belonging to the first group 12, the number of the electrically powered lawn mowers 18 belonging to the second group 16, and the number of the household electrical power storage devices 22 belonging to the third group 20.

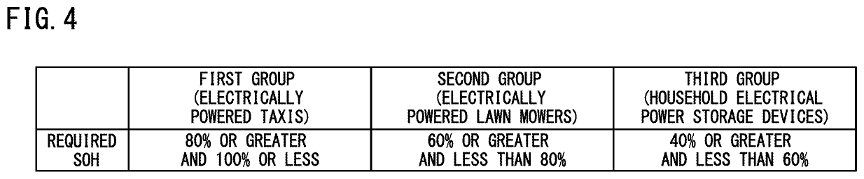

The degree of degradation range storage unit 40 stores a range (hereinafter referred to as a required SOH range) of SOH of the battery required for each of the electrically powered taxis 14, the electrically powered lawn mowers 18, and the household electrical power storage devices 22. In the degree of degradation range storage unit 40, there may be stored a range of the number of charging times required for each of the electrically powered taxis 14, the electrically powered lawn mowers 18, and the household electrical power storage devices 22 (hereinafter referred to as a required number of charging times) or a range of the number of discharging times required therefor (hereinafter referred to as a required number of discharging times). FIG. 4 is a table showing an example of the required SOH range stored in the degree of degradation range storage unit 40. In the electrically powered taxis 14, an SOH within a range of greater than or equal to 80% and less than or equal to 100% is required. In the electrically powered lawn mowers 18, an SOH within a range of greater than or equal to 60% and less than 80% is required. In the third group 20, an SOH within a range of greater than or equal to 40% and less than 60% is required. Moreover, it should be noted that the required SOH range shown in FIG. 4 is only one example, and other required SOH ranges may be used. For example, the required SOH range of the electrically powered taxis 14 may be set to a required SOH range that allows the electrically powered taxis 14 to travel a predetermined distance or more in a state in which the batteries in the electrically powered taxis 14 are fully charged. Further, the required SOH range of the electrically powered lawn mowers 18 may be set to a required SOH range that allows the electrically powered lawn mowers 18 to be driven for a predetermined time period or more in a state in which the batteries in the electrically powered lawn mowers 18 are fully charged. Further, the required SOH range of the household electrical power storage devices 22 may be set to a required SOH range in which the household electrical power storage device 22 can ensure a predetermined electrical power capacity (Ah) or greater.

In the present embodiment, although three groups, i.e., the first group 12, the second group 16, and the third group 20, are set, three or more of such groups may be set.

According to the present embodiment, although the electrically powered taxis 14 belong to the first group 12, the electrically powered lawn mowers 18 belong to the second group 16, and the household electrical power storage devices 22 belong to the third group 20, the types of the electrically powered products belonging to each of the groups may be different types of electrically powered products. Based on average values of previously acquired operation information data, the electrically powered products may be classified into the first group 12, the second group 16, and the third group 20, in order from the largest required amount of electrical power or from the highest required SOH thereof.

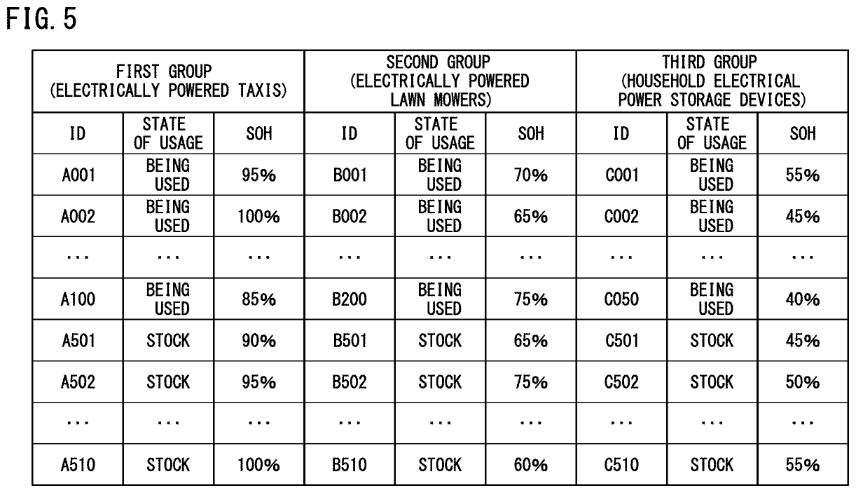

The state of usage storage unit 42 stores the states of usage of the batteries in each of the first group 12, the second group 16, and the third group 20. FIG. 5 is a table showing an example of the contents of battery usage states stored in the state of usage storage unit 42. The state of usage storage unit 42 stores information of the IDs of the batteries that belong respectively to the first group 12, the second group 16, and the third group 20, a state of usage indicating whether each of the batteries is currently in use or is held in inventory, and the SOH for each of the batteries. Moreover, instead of the SOH for each of the batteries, the state of usage storage unit 42 may store the number of charging times or the number of discharging times of each of the batteries.

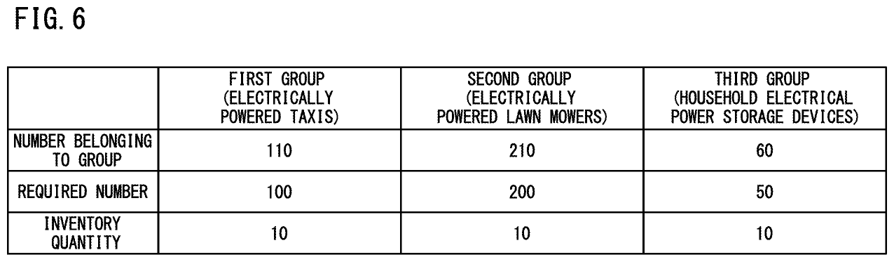

The number storage unit 44 stores a number of batteries belonging to each group, a required number of batteries, and an inventory quantity of the batteries in each of the first group 12, the second group 16, and the third group 20. FIG. 6 is a table showing an example of the number of batteries belonging to each group, the required number of batteries, and the inventory quantity of the batteries, which are stored in the number storage unit 44.

On the basis of the information stored in the degree of degradation range storage unit 40, the state of usage storage unit 42, and the number storage unit 44, the distribution unit 46 issues instructions for the collection or the delivery of the batteries to or from the production plant 10, the first battery collection site 32, the second battery collection site 34, and the recycling plant 24.

The inventory management system 26 includes a computer having a non-illustrated arithmetic processing unit and a storage unit. The arithmetic processing unit, for example, comprises a central processing unit (CPU), a processor such as a micro-processing unit (MPU) or the like, and a memory made up from a non-transitory or a transitory tangible computer readable recording medium such as a ROM, a RAM, or the like. The storage for example, is a non-transitory tangible computer readable recording medium such as a hard disk, a solid state drive (SSD), or the like.

The degree of degradation acquisition unit 36, the required number acquisition unit 38, and the distribution unit 46 are implemented by the arithmetic processing unit executing programs stored in the storage unit. The degree of degradation range storage unit 40, the state of usage storage unit 42, and the number storage unit 44 are storage areas that store respective items of information.

### [Distribution Process]

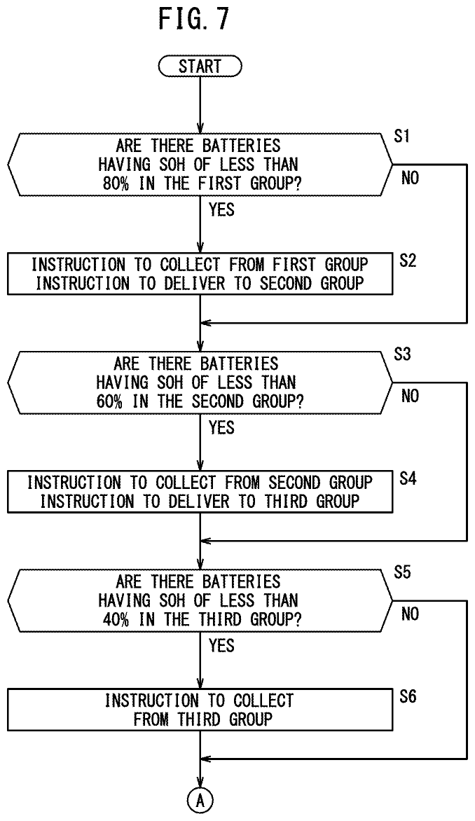

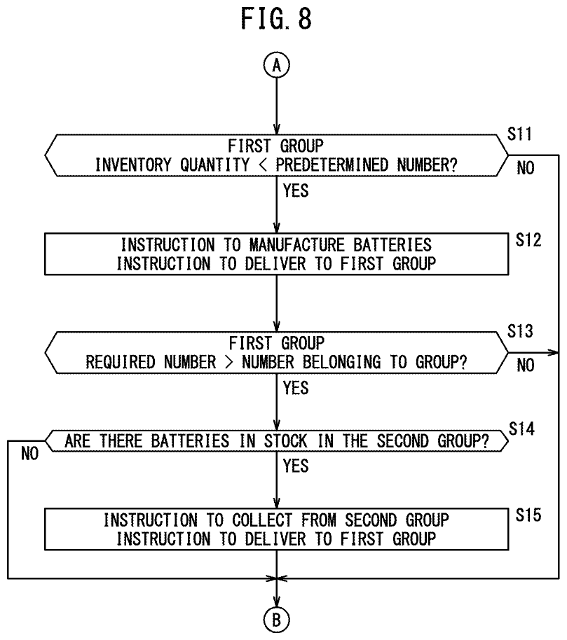

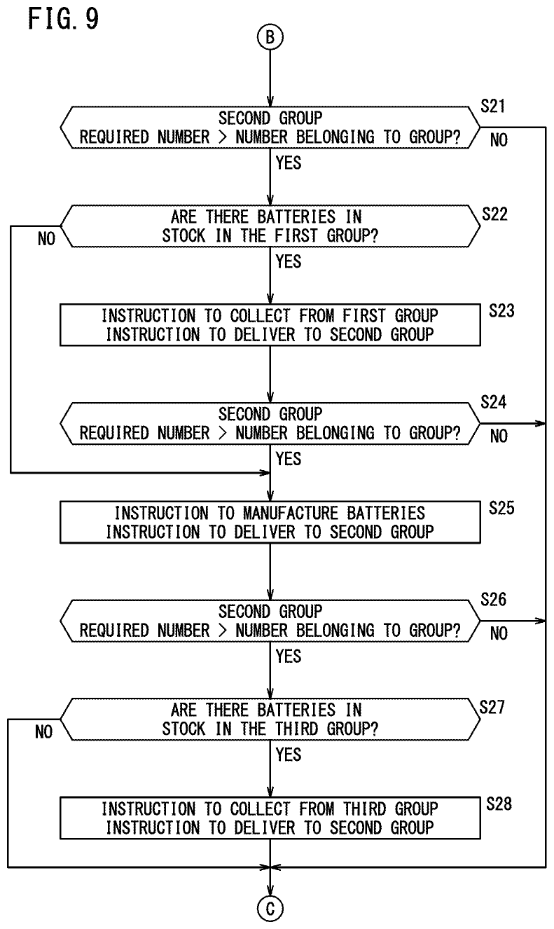

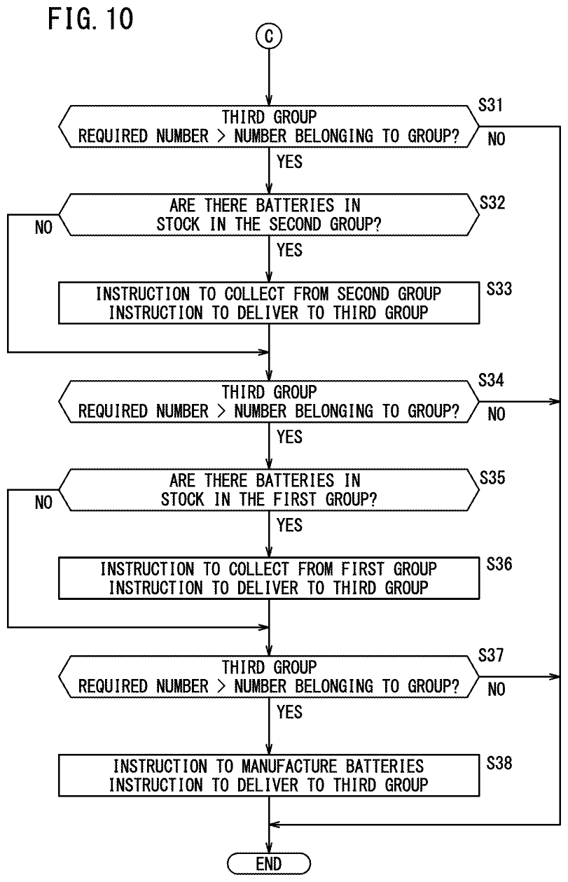

FIGS. 7 to 10 are flow charts showing a process flow of a distribution process performed by the distribution unit 46. The distribution process is executed repeatedly at a predetermined cycle.

In step S1, the distribution unit 46 determines whether or not there are batteries having an SOH of less than 80%, in the first group 12. In the case that batteries having an SOH of less than 80% are included in the first group 12, the process transitions to step S2, whereas in the case that batteries having an SOH of less than 80% are not included in the first group 12, the process transitions to step S3. In step S1, the distribution unit 46 may also determine whether or not there are batteries, in the first group 12, that have been subjected to charging for greater than or equal to 750 times, or alternatively, subjected to discharging for greater than or equal to 750 times.

In step S2, the distribution unit 46 rewrites the state of usage storage unit 42 and the number storage unit 44, in a manner so that the batteries belonging to the first group 12 and having an SOH of less than 80% are made to belong to the second group 16. Stated otherwise, from among the batteries associated with the electrically powered taxis 14, the distribution unit 46 associates batteries that have an SOH of less than 80%, with the electrically powered lawn mowers 18. In addition, the distribution unit 46 issues an instruction to the first battery collection site 32 to collect the batteries having an SOH of less than 80% from the first group 12 and to deliver the collected batteries to the second group 16, whereupon the process transitions to step S3. In step S2, the distribution unit 46 may also rewrite the state of usage storage unit 42 and the number storage unit 44, in a manner so that the batteries belonging to the first group 12 and having the number of charging times of greater than or equal to 750 times, or alternatively, having the number of discharging times of greater than or equal to 750 times are made to belong to the second group 16. In addition, the distribution unit 46 may issue an instruction to the first battery collection site 32 so as to collect the batteries having the number of charging times of greater than or equal to 750 times or alternatively having the number of discharging times of greater than or equal to 750 times from the first group 12 and to deliver the collected batteries to the second group 16.

In step S3, the distribution unit 46 determines whether or not there are batteries, in the second group 16, having an SOH of less than 60%. In the case that batteries having an SOH of less than 60% are included in the second group 16, the process transitions to step S4, whereas in the case that batteries having an SOH of less than 60% are not included in the second group 16, the process transitions to step S5. In step S3, the distribution unit 46 may also determine whether or not there are batteries, in the second group 16, that have been subjected to charging for greater than or equal to 950 times, or alternatively, subjected to discharging for greater than or equal to 950 times.

In step S4, the distribution unit 46 rewrites the state of usage storage unit 42 and the number storage unit 44, in a manner so that the batteries belonging to the second group 16 and having an SOH of less than 60% are made to belong to the third group 20. Stated otherwise, from among the batteries associated with the electrically powered lawn mowers 18, the distribution unit 46 associates batteries that have an SOH of less than 60%, with the household electrical power storage devices 22. In addition, the distribution unit 46 issues, to the second battery collection site 34, an instruction to collect the batteries having an SOH of less than 60% from the second group 16 and to deliver the collected batteries to the third group 20, whereupon the process transitions to step S5. In step S4, the distribution unit 46 may also rewrite the state of usage storage unit 42 and the number storage unit 44, in a manner so that the batteries belonging to the second group 16 and having the number of charging times of greater than or equal to 950 times, or alternatively, having the number of discharging times of greater than or equal to 950 times are made to belong to the third group 20. In addition, the distribution unit 46 may issue an instruction to the second battery collection site 34 to collect the batteries having the number of charging times of greater than or equal to 950 times, or alternatively, having the number of discharging times of greater than or equal to 950 times from the second group 16 and to deliver the collected batteries to the third group 20.

In step S5, the distribution unit 46 determines whether or not there are batteries having an SOH of less than 40% in the third group 20. In the case that batteries having an SOH of less than 40% are included in the third group 20, the process transitions to step S6, whereas in the case that batteries having an SOH of less than 40% are not included in the third group 20, the process transitions to step S11. In step S5, the distribution unit 46 may also determine whether or not there are batteries, in the third group 20, that have been subjected to charging for greater than or equal to 1000 times, or alternatively, subjected to discharging for greater than or equal to 1000 times.

In step S6, the distribution unit 46 rewrites the state of usage storage unit 42 and the number storage unit 44, in a manner so that the batteries belonging to the third group 20 and having an SOH of less than 40% are excluded from the third group 20. Stated otherwise, among the batteries associated with the household electrical power storage devices 22, the distribution unit 46 excludes those batteries having an SOH of less than 40% from the association with the household electrical power storage devices 22. In addition, the distribution unit 46 issues an instruction to the recycling plant 24 so as to collect the batteries having an SOH of less than 40% from the third group 20, whereupon the process transitions to step S11. In step S6, the distribution unit 46 may also rewrite the state of usage storage unit 42 and the number storage unit 44, in a manner so that the batteries belonging to the third group 20 and having the number of charging times of greater than or equal to 1000 times, or alternatively, having the number of discharging times of greater than or equal to 1000 times are excluded from the third group 20. In addition, the distribution unit 46 may issue an instruction to the recycling plant 24 so as to collect the batteries having the number of charging times of greater than or equal to 1000 times, or alternatively, having the number of discharging times of greater than or equal to 1000 times from the third group 20.

In step S11, the distribution unit 46 determines whether or not the inventory quantity in the first group 12 is less than a predetermined number. In the case that the inventory quantity in the first group 12 is less than the predetermined number, the process transitions to step S12, whereas in the case that the inventory quantity in the first group 12 is greater than or equal to the predetermined number, the process transitions to step S21.

In step S12, the distribution unit 46 issues an instruction to the production plant 10 to manufacture the batteries. Further, the distribution unit 46 rewrites the state of usage storage unit 42 and the number storage unit 44, in a manner so that the batteries manufactured in the production plant 10 are made to belong to the first group 12. Stated otherwise, the distribution unit 46 associates the batteries manufactured by the production plant 10 with the electrically powered taxis 14. In addition, an instruction is issued to the production plant 10 so as to deliver the manufactured batteries to the first group 12, whereupon the process transitions to step S13.

In step S13, the distribution unit 46 determines whether or not the required number of batteries in the first group 12 is greater than the number of batteries belonging thereto. In the case that the required number of batteries in the first group 12 is greater than the number of batteries belonging thereto, the process transitions to step S14, whereas in the case that the required number of batteries in the first group 12 is less than or equal to the number of batteries belonging thereto, the process transitions to step S21.

In step S14, the distribution unit 46 determines whether or not there are batteries in stock in the second group 16. In the case that there are batteries in stock therein, the process transitions to step S15, whereas in the case that there are not batteries in stock therein, the process transitions to step S21.

In step S15, the distribution unit 46 rewrites the state of usage storage unit 42 and the number storage unit 44, in a manner so that, among the batteries that are stored as inventory in the second group 16, the batteries are made to belong to the first group 12, in order from the highest SOH of the batteries (i.e., in order from the lowest degree of degradation of the batteries). Stated otherwise, among the batteries associated with the electrically powered lawn mowers 18 but which are not currently being used by the electrically powered lawn mowers 18, the distribution unit 46 associates the batteries with the electrically powered taxis 14, in order from the highest SOH thereof (i.e., in order from the lowest degree of degradation thereof). In addition, the distribution unit 46 issues, to the first battery collection site 32, an instruction so as to collect the batteries that are stored as inventory in the second group 16, from the second group 16, sequentially in order from the highest SOH thereof (i.e., in order from the lowest degree of degradation thereof) and so as to deliver the collected batteries to the first group 12, whereupon the process transitions to step S21. In step S15, the distribution unit 46 may rewrite the state of usage storage unit 42 and the number storage unit 44, in a manner so that, among the batteries that are stored as inventory in the second group 16, the batteries are made to belong to the first group 12, in order from the smallest number of charging times of the batteries or from the smallest number of discharging times of the batteries (i.e., in order from the lowest degree of degradation thereof). In addition, the distribution unit 46 may issues, to the first battery collection site 32, an instruction so as to collect the batteries that are stored as inventory in the second group 16, from the second group 16, sequentially in order from the smallest number of charging times thereof or from the smallest number of discharging times thereof (i.e., in order from the lowest degree of degradation thereof) and so as to deliver the collected batteries to the first group 12.

In step S21, the distribution unit 46 determines whether or not the required number of batteries in the second group 16 is greater than the number of batteries belonging to the second group. In the case that the required number thereof in the second group 16 is greater than the number thereof belonging thereto, the process transitions to step S22, whereas in the case that the required number in the second group 16 is less than or equal to the number belonging thereto, the process transitions to step S31.

In step S22, the distribution unit 46 determines whether or not there are batteries in stock in the first group 12. In the case that there are batteries in stock therein, the process transitions to step S23, whereas in the case that there are not batteries in stock therein, the process transitions to step S25.

In step S23, the distribution unit 46 rewrites the state of usage storage unit 42 and the number storage unit 44, in a manner so that, among the batteries that are stored as inventory in the first group 12, the batteries are made to belong to the second group 16, in order from the lowest SOH thereof (i.e., from the highest degree of degradation thereof). Stated otherwise, from among the batteries associated with the electrically powered taxis 14 but which are not currently being used by the electrically powered taxis 14, the distribution unit 46 associates the batteries with the electrically powered lawn mowers 18, in order from the lowest SOH thereof (i.e., from the highest degree of degradation thereof). In addition, the distribution unit 46 issues, to the first battery collection site 32, an instruction so as to collect the batteries that are stored as inventory in the first group 12, from the first group 12, in order from the lowest SOH thereof (i.e., from the highest degree of degradation thereof) and so as to deliver the collected batteries to the second group 16, whereupon the process transitions to step S24. In step S23, the distribution unit 46 may rewrite the state of usage storage unit 42 and the number storage unit 44, in a manner so that, among the batteries that are stored as inventory in the first group 12, the batteries are made to belong to the second group 16, in order from the largest number of charging times thereof or from the largest number of discharging times thereof (i.e., in order from the highest degree of degradation thereof). In addition, the distribution unit 46 may issue, to the first battery collection site 32, an instruction so as to collect the batteries that are stored as inventory in the first group 12, from the first group 12, in order from the largest number of charging times thereof or from the largest number of discharging times thereof (i.e., in order from the highest degree of degradation thereof) and so as to deliver the collected batteries to the second group 16.

In step S24, the distribution unit 46 determines whether or not the required number of batteries in the second group 16 is greater than the number of batteries belonging to the second group. In the case that the required number in the second group 16 is greater than the number belonging thereto, the process transitions to step S25, whereas in the case that the required number of the second group 16 is less than or equal to the number belonging thereto, the process transitions to step S31.

In step S25, the distribution unit 46 issues an instruction to the production plant 10 to manufacture the batteries. Further, the distribution unit 46 rewrites the state of usage storage unit 42 and the number storage unit 44, in a manner so that the batteries manufactured in the production plant 10 are made to belong to the second group 16. Stated otherwise, the distribution unit 46 associates the batteries manufactured by the production plant 10 with the electrically powered lawn mowers 18. In addition, an instruction is issued to the production plant 10 so as to deliver the manufactured batteries to the second group 16, whereupon the process transitions to step S26.

In step S26, the distribution unit 46 determines whether or not the required number of batteries in the second group 16 is greater than the number of batteries belonging to the second group. In the case that the required number in the second group 16 is greater than the number belonging thereto, the process transitions to step S27, whereas in the case that the required number of the second group 16 is less than or equal to the number belonging thereto, the process transitions to step S31.

In step S27, the distribution unit 46 determines whether or not there are batteries in stock in the third group 20. In the case that there are batteries in stock therein, the process transitions to step S28, whereas in the case that there are not batteries in stock therein, the process transitions to step S31.

In step S28, the distribution unit 46 rewrites the state of usage storage unit 42 and the number storage unit 44, in a manner so that, among the batteries that are stored as inventory in the third group 20, the batteries are made to belong to the second group 16, in order from the highest SOH thereof (i.e., in order from the lowest degree of degradation thereof). Stated otherwise, from among the batteries associated with the household electrical power storage devices 22 but which are not currently being used by the household electrical power storage devices 22, the distribution unit 46 associates the batteries with the electrically powered lawn mowers 18, in order from the highest SOH thereof (i.e., from the lowest degree of degradation thereof). In addition, the distribution unit 46 issues, to the second battery collection site 34, an instruction so as to collect the batteries that are stored as inventory in the third group 20, from the third group 20, in order from the highest SOH thereof (i.e., in order from the lowest degree of degradation thereof) and so as to deliver the collected batteries to the second group 16, whereupon the process transitions to step S31. In step S28, the distribution unit 46 rewrites the state of usage storage unit 42 and the number storage unit 44, in a manner so that, among the batteries that are stored as inventory in the third group 20, the batteries are made to belong to the second group 16, in order from the smallest number of charging times thereof or from the smallest number of discharging times thereof (i.e., in order from the lowest degree of degradation thereof). In addition, the distribution unit 46 may issue, to the second battery collection site 34, an instruction so as to collect the batteries that are stored as inventory in the third group 20, from the third group 20, in order from the smallest number of charging times thereof or from the smallest number of discharging times thereof (i.e., in order from the lowest degree of degradation thereof) and so as to deliver the collected batteries to the second group 16.

In step S31, the distribution unit 46 determines whether or not the required number of batteries in the third group 20 is greater than the number of batteries belonging to the third group. In the case that the required number in the third group 20 is greater than the number belonging thereto, the process transitions to step S32, whereas in the case that the required number of the third group 20 is less than or equal to the number belonging thereto, the distribution process is brought to an end.

In step S32, the distribution unit 46 determines whether or not there are batteries in stock in the second group 16. In the case that there are batteries in stock therein, the process transitions to step S33, whereas in the case that there are not batteries in stock therein, the process transitions to step S34.

In step S33, the distribution unit 46 rewrites the state of usage storage unit 42 and the number storage unit 44, in a manner so that, among the batteries that are stored as inventory in the second group 16, the batteries are made to belong to the third group 20, in order from the lowest SOH thereof (i.e., from the highest degree of degradation thereof). Stated otherwise, from among the batteries that are associated with the electrically powered lawn mowers 18 but which are not currently being used by the electrically powered lawn mowers 18, the distribution unit 46 associates the batteries with the household electrical power storage devices 22, in order from the lowest SOH thereof (i.e., from the highest degree of degradation thereof). In addition, the distribution unit 46 issues, to the second battery collection site 34, an instruction so as to collect the batteries that are stored as inventory in the second group 16, from the second group 16, in order from the lowest SOH thereof (i.e., from the highest degree of degradation thereof) and so as to deliver the collected batteries to the third group 20, whereupon the process transitions to step S34. In step S33, the distribution unit 46 may rewrite the state of usage storage unit 42 and the number storage unit 44, in a manner so that, among the batteries that are stored as inventory in the second group 16, the batteries are made to belong to the third group 20, in order from the largest number of charging times thereof or from the largest number of discharging times thereof (i.e., in order from the highest degree of degradation thereof). In addition, the distribution unit 46 may issue, to the second battery collection site 34, an instruction so as to collect the batteries that are stored as inventory in the second group 16, from the second group 16, in order from the largest number of charging times thereof or from the largest number of discharging times thereof (i.e., in order from the highest degree of degradation thereof) and so as to deliver the collected batteries to the third group 20.

In step S34, the distribution unit 46 determines whether or not the required number of batteries in the third group 20 is greater than the number of batteries belonging to the third group. In the case that the required number of batteries in the third group 20 is greater than the number of batteries belonging to the third group, the process transitions to step S35, whereas in the case that the required number in the third group 20 is less than or equal to the number belonging thereto, the distribution process is brought to an end.

In step S35, the distribution unit 46 determines whether or not there are batteries in stock in the first group 12. In the case that there are batteries in stock therein, the process transitions to step S36, whereas in the case that there are not batteries in stock therein, the process transitions to step S37.

In step S36, the distribution unit 46 rewrites the state of usage storage unit 42 and the number storage unit 44, in a manner so that, among the batteries that are stored as inventory in the first group 12, the batteries are made to belong to the third group 20, in order from the lowest SOH thereof (i.e., from the highest degree of degradation thereof). Stated otherwise, from among the batteries associated with the electrically powered taxis 14 but which are not currently being used by the electrically powered taxis 14, the distribution unit 46 associates the batteries with the household electrical power storage devices 22, in order from the lowest SOH thereof (i.e., from the highest degree of degradation thereof). In addition, the distribution unit 46 issues, to the first battery collection site 32, an instruction so as to collect the batteries that are stored as inventory in the first group 12, from the first group 12, in order from the lowest SOH thereof (i.e., from the highest degree of degradation thereof) and so as to deliver the collected batteries to the third group 20, whereupon the process transitions to step S37. In step S36, the distribution unit 46 may rewrite the state of usage storage unit 42 and the number storage unit 44, in a manner so that, among the batteries that are stored as inventory in the first group 12, the batteries are made to belong to the third group 20, in order from the largest number of charging times thereof or from the largest number of discharging times thereof (i.e., in order from the highest degree of degradation thereof). In addition, the distribution unit 46 may issue, to the first battery collection site 32, an instruction so as to collect the batteries that are stored as inventory in the first group 12, from the first group 12, in order from the largest number of charging times thereof or from the largest number of discharging times thereof (i.e., in order from the highest degree of degradation thereof) and so as to deliver the collected batteries to the third group 20.

In step S37, the distribution unit 46 determines whether or not the required number of batteries in the third group 20 is greater than the number of batteries belonging to the third group. In the case that the required number of batteries in the third group 20 is greater than the number thereof belonging to the third group, the process transitions to step S38, whereas in the case that the required number of the third group 20 is less than or equal to the number belonging thereto, the distribution process is brought to an end.

In step S38, the distribution unit 46 issues an instruction to the production plant 10 to manufacture the batteries. Further, the distribution unit 46 rewrites the state of usage storage unit 42 and the number storage unit 44, in a manner so that the batteries manufactured in the production plant 10 are made to belong to the third group 20. Stated otherwise, the distribution unit 46 associates the batteries manufactured by the production plant 10 with the household electrical power storage devices 22. In addition, an instruction is issued to the production plant 10 so as to deliver the manufactured batteries to the third group 20, whereupon the process is brought to an end.

### [Concerning Movement of the Batteries]

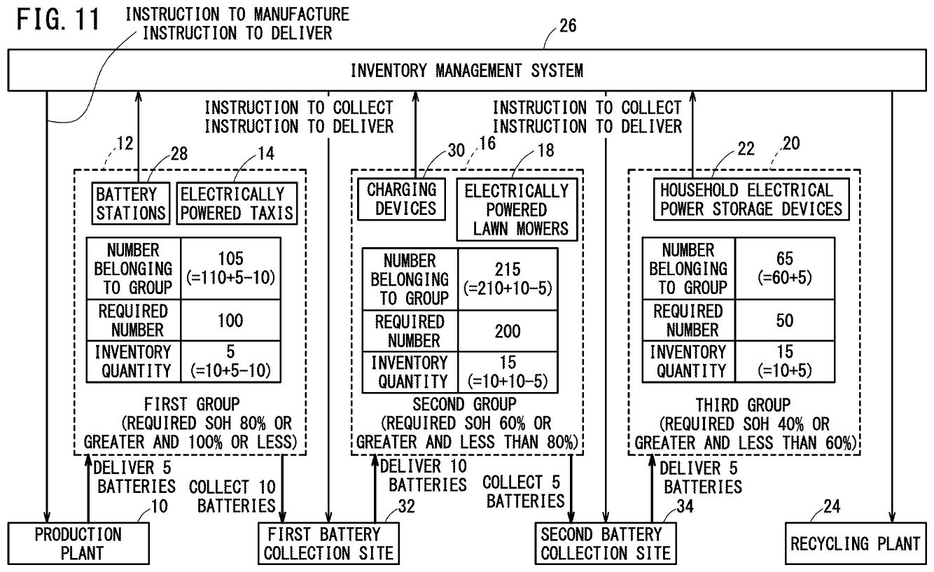

FIG. 11 to FIG. 17, similar to FIG. 2, are diagrams for describing the distribution of batteries in each of the first group 12, the second group 16, and the third group 20. Hereinafter, movement of the batteries will be described with reference to a specific example. In the current state, as shown in FIG. 2, the number of batteries belonging to the first group 12 is 110, the required number thereof is 100, and the inventory quantity thereof is 10. The number of batteries belonging to the second group 16 is 210, the required number thereof is 200, and the inventory quantity thereof is 10. The number of batteries belonging to the third group 20 is 60, the required number thereof is 50, and the inventory quantity thereof is 10.

In this instance, from among the batteries belonging to the first group 12, it is assumed that the number of batteries having an SOH of less than 80% is 10, and from among the batteries belonging to the second group 16, the number of batteries having an SOH of less than 60% is 5.

In this case, as shown in FIG. 11, an instruction to collect 10 batteries having an SOH of less than 80% from the first group 12 and deliver the collected 10 batteries to the second group 16, is output from the inventory management system 26 to the first battery collection site 32. In accordance with the instruction, the first battery collection site 32 collects the 10 batteries having an SOH of less than 80% from the first group 12, and delivers the 10 batteries that have been collected to the second group 16.

Similarly, as shown in FIG. 11, an instruction to collect 5 batteries having an SOH of less than 60% from the second group 16 and deliver the collected 5 batteries to the third group 20, is output from the inventory management system 26 to the second battery collection site 34. In accordance with the instruction, the second battery collection site 34 collects the 5 batteries from the second group 16, and delivers the 5 batteries that have been collected to the third group 20.

Since the inventory quantity of the batteries in the first group 12 has become zero, and has become less than the predetermined number (for example, 5), an instruction to manufacture 5 batteries and deliver the 5 batteries that have been manufactured to the first group 12 is output from the inventory management system 26 to the production plant 10. In accordance with the instruction, the production plant 10 manufactures the 5 batteries, and delivers the 5 batteries that have been manufactured to the first group 12.

As a result, as shown in FIG. 11, the number of batteries belonging to the first group 12 is 105, the required number thereof is 100, and the inventory quantity thereof is 5. The number of batteries belonging to the second group 16 is 215, the required number thereof is 200, and the inventory quantity thereof is 15. The number of batteries belonging to the third group 20 is 65, the required number thereof is 50, and the inventory quantity thereof is 15.

Even batteries that have ceased to satisfy the required SOH of the electrically powered taxis 14 are still capable of satisfying the required SOH of the electrically powered lawn mowers 18. By using the batteries that have ceased to satisfy the required SOH of the electrically powered taxis 14, in the electrically powered lawn mowers 18, the batteries can be reused without lowering the performance of the driving time period of the electrically powered lawn mowers 18. Similarly, even batteries that have ceased to satisfy the required SOH of the electrically powered lawn mowers 18 are still capable of satisfying the required SOH of the household electrical power storage devices 22. By using the batteries that have ceased to satisfy the required SOH of the electrically powered lawn mowers 18, in the household electrical power storage devices 22, the batteries can be reused without lowering the electrical power time performance of the household electrical power storage devices 22.

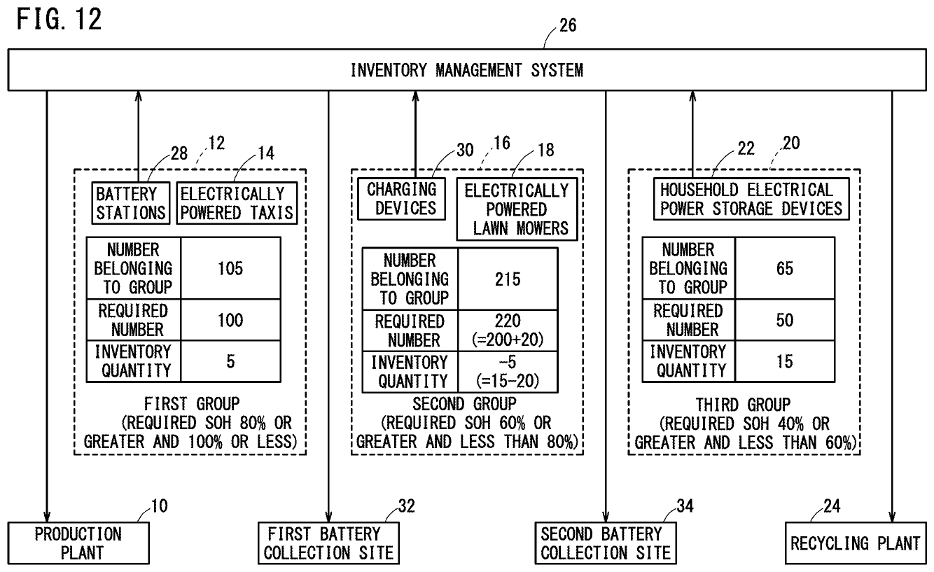

Next, as shown in FIG. 12, it is assumed that the number of the electrically powered lawn mowers 18 belonging to the second group 16 has increased, and the required number of batteries of the second group 16 has increased to 220 batteries. Therefore, a state is brought about in which the second group 16 is short of 5 batteries.

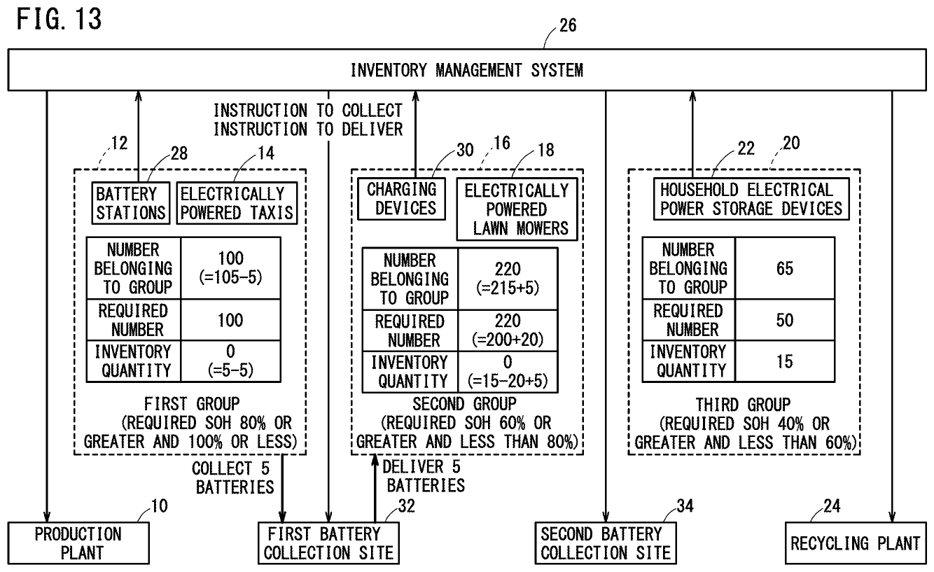

In this case, as shown in FIG. 13, an instruction to collect 5 batteries from among the batteries that are stored as inventory in the first group 12, sequentially in order from the lowest SOH thereof (i.e., from the highest degree of degradation thereof) and to deliver the collected 5 batteries to the second group 16, is output from the inventory management system 26 to the first battery collection site 32. In accordance with the instruction, the first battery collection site 32 collects the 5 batteries from among the batteries that are stored as inventory in the first group 12, sequentially in order from the lowest SOH thereof (i.e., from the highest degree of degradation thereof), and delivers the collected 5 batteries to the second group 16.

As a result, as shown in FIG. 13, the number of batteries belonging to the first group 12 is 100, the required number thereof is 100, and the inventory quantity thereof is 0. The number of batteries belonging to the second group 16 is 220, the required number thereof is 220, and the inventory quantity thereof is 0. The number of batteries belonging to the third group 20 is 65, the required number thereof is 50, and the inventory quantity thereof is 15.

Consequently, the shortage in the required number of batteries for the electrically powered lawn mowers 18 can be compensated with supply of the batteries in stock of the first group 12 to the second group 16, and all of the electrically powered lawn mowers 18 are capable of utilizing the batteries. Further, since the SOH of the batteries supplied from the first group 12 to the second group 16 is higher than the required SOH for the electrically powered lawn mowers 18, the electrically powered lawn mowers 18 are capable of being driven for greater than or equal to a predetermined driving time period, and the performance of the driving time period of the electrically powered lawn mowers 18 can be ensured.

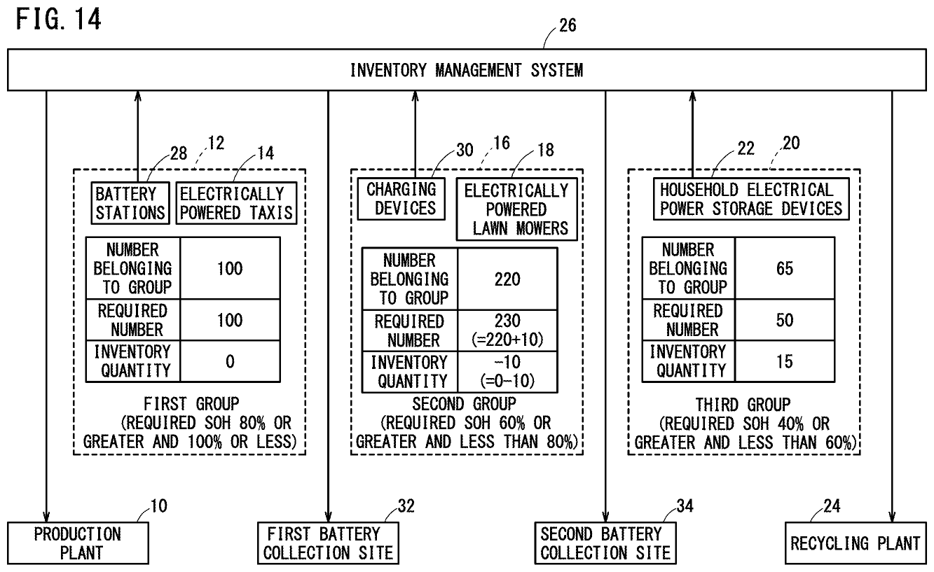

Next, as shown in FIG. 14, it is assumed that the number of the electrically powered lawn mowers 18 belonging to the second group 16 has increased, and the required number of batteries in the second group 16 has increased to 230 batteries. Therefore, a state is brought about in which the second group 16 is short of 10 batteries.

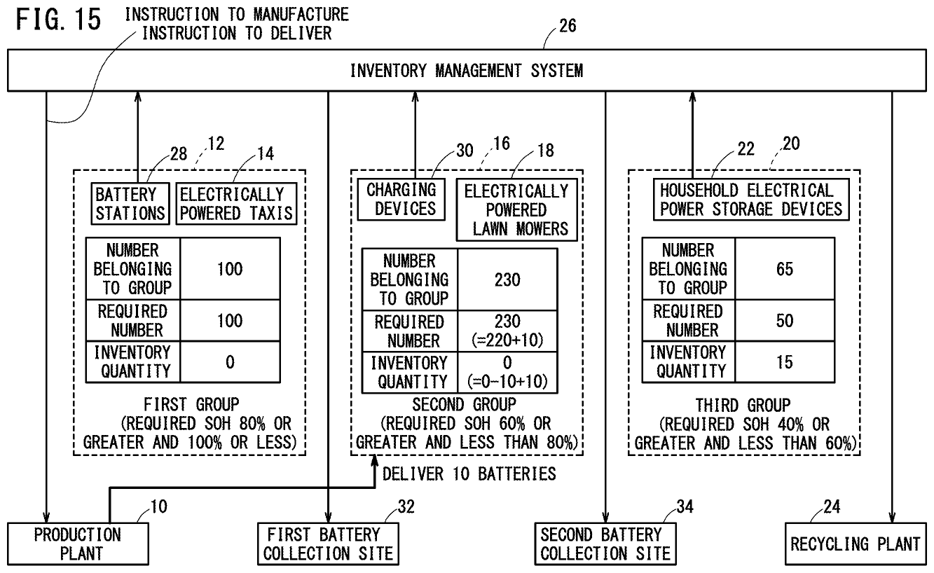

In this case, as shown in FIG. 15, an instruction to manufacture 10 batteries and deliver the 10 batteries that were manufactured to the second group 16, is output from the inventory management system 26 to the production plant 10. In accordance with the instruction, the production plant 10 manufactures the 10 batteries, and delivers the 10 batteries that have been manufactured to the second group 16.

As a result, as shown in FIG. 15, the number of batteries belonging to the first group 12 is 100, the required number thereof is 100, and the inventory quantity thereof is 0. The number of batteries belonging to the second group 16 is 230, the required number thereof is 230, and the inventory quantity thereof is 0. The number of batteries belonging to the third group 20 is 65, the required number thereof is 50, and the inventory quantity thereof is 15.

Consequently, the shortage in the required number of batteries for the electrically powered lawn mowers 18 can be made up for with supply of the batteries from the production plant 10 to the second group 16, and all of the electrically powered lawn mowers 18 are capable of utilizing the batteries. Further, since the SOH of the batteries supplied from the production plant 10 is higher than the required SOH for the electrically powered lawn mowers 18, the electrically powered lawn mowers 18 are capable of being driven for greater than or equal to a predetermined driving time period, and the performance of the driving time period of the electrically powered lawn mowers 18 can be ensured.

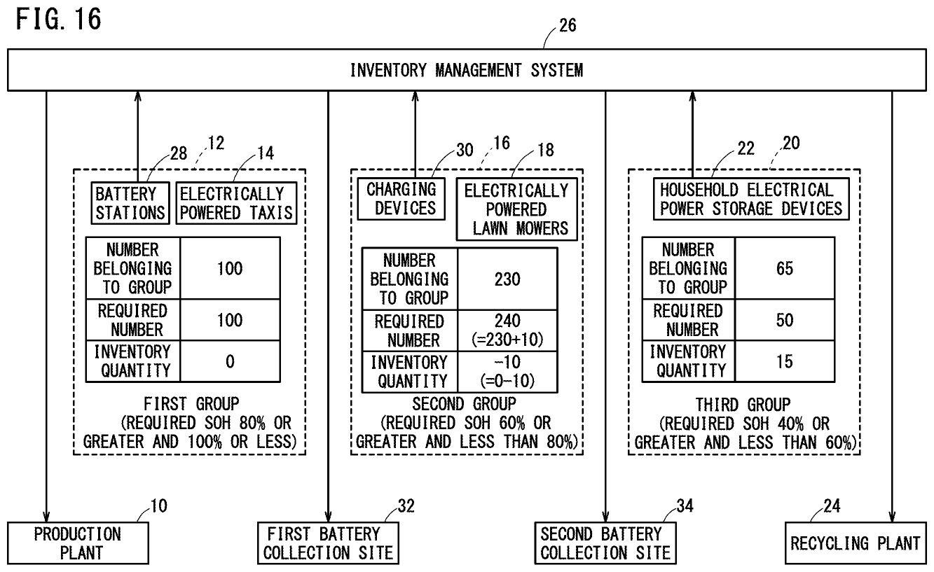

Next, as shown in FIG. 16, it is assumed that the number of the electrically powered lawn mowers 18 belonging to the second group 16 has increased, and the required number of batteries of the second group 16 has increased to 240 batteries. Therefore, a state is brought about in which the second group 16 is short of 10 batteries. In this instance, it is assumed that the battery production capacity of the production plant 10 is in a saturated state, and therefore the batteries cannot be supplied from the production plant 10.

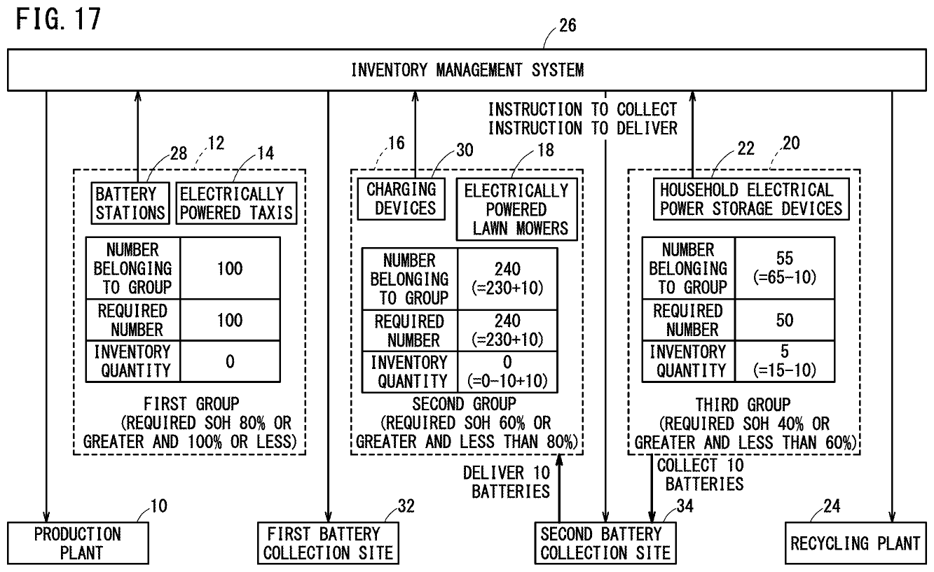

In this case, as shown in FIG. 17, an instruction to collect 10 batteries from among the batteries that are stored as inventory in the third group 20, sequentially in order from the highest SOH thereof (i.e., from the lowest degree of degradation thereof) and to deliver the collected 10 batteries to the second group 16, is output from the inventory management system 26 to the second battery collection site 34. In accordance with the instruction, the second battery collection site 34 collects the 10 batteries from among the batteries that are stored as inventory in the third group 20, sequentially in order from the highest SOH thereof (i.e., from the lowest degree of degradation thereof), and delivers the collected 10 batteries to the second group 16.

As a result, as shown in FIG. 17, the number of batteries belonging to the first group 12 is 100, the required number thereof is 100, and the inventory quantity thereof is 0. The number of batteries belonging to the second group 16 is 240, the required number thereof is 240, and the inventory quantity thereof is 0. The number of batteries belonging to the third group 20 is 55, the required number thereof is 50, and the inventory quantity thereof is 5.

Consequently, the shortage in the required number of batteries for the electrically powered lawn mowers 18 can be compensated with transfer of the batteries in stock of the third group 20 to the second group 16, and all of the electrically powered lawn mowers 18 are capable of utilizing the batteries. In this case, since the SOH of the batteries transferred from the third group 20 to the second group 16 is lower than the required SOH for the electrically powered lawn mowers 18, the electrically powered lawn mowers 18 are incapable of being driven for greater than or equal to the predetermined driving time period. Although the performance of the driving time period of the electrically powered lawn mowers 18 is decreased, priority is given to satisfying the required number of batteries for the electrically powered lawn mowers 18. By transferring the batteries, from among the batteries stored as inventory in the third group 20, to the second group 16, in order from the highest SOH thereof (i.e., from the lowest degree of degradation thereof), batteries that are closer to the required SOH of the second group 16 (the electrically powered lawn mowers 18) can be delivered, and a decrease in the performance of the driving time period of the electrically powered lawn mowers 18 can be suppressed.

### [Operations and Advantageous Effects]

In the inventory management system 26 according to the present embodiment, among the batteries belonging to the first group 12 in order to be used by the electrically powered taxis 14, batteries having an SOH of less than 80% are transferred to the second group 16 in order to be used by the electrically powered lawn mowers 18. Consequently, batteries that no longer satisfy the required SOH of the electrically powered taxis 14 can be reused by the electrically powered lawn mowers 18. Similarly, in the inventory management system 26 according to the present embodiment, among the batteries belonging to the second group 16 in order to be used by the electrically powered lawn mowers 18, batteries having an SOH of less than 60% are made to belong to the third group 20 in order to be used by the household electrical power storage devices 22. As a result, batteries that no longer satisfy the required SOH of the electrically powered lawn mowers 18 can be reused by the household electrical power storage devices 22.

In the inventory management system 26 according to the present embodiment, the required SOH range for the electrically powered taxis 14 and the required SOH range for the electrically powered lawn mowers 18 are set continuously. Further, in the inventory management system 26 according to the present embodiment, the required SOH range for the electrically powered lawn mowers 18 and the required SOH range for the household electrical power storage devices 22 are set continuously. In accordance with this feature, since the SOHs of the batteries always fall within the required SOH range for one of the types of electrically powered products, the opportunity of reusing the batteries can be increased.

In the inventory management system 26 according to the present embodiment, the number of batteries belonging to each of the groups and the required number of batteries in each of the types of the electrically powered products are associated with each other, and are stored in the number storage unit 44. Consequently, it is possible to determine an excess or a deficiency of the batteries in each of the types of the electrically powered products.

In the inventory management system 26 according to the present embodiment, the SOHs of the batteries belonging to each of the groups are stored in the state of usage storage unit 42. Consequently, in accordance with the SOHs of the batteries, it is possible to determine which ones of the batteries are to be transferred to the other groups for use in other types of the electrically powered products.

In the inventory management system 26 according to the present embodiment, in the case that the required number of batteries for the electrically powered lawn mowers 18 is greater than the number of batteries belonging to the second group 16, from among the batteries belonging to the first group 12 for use in the electrically powered taxis 14, batteries are transferred to the second group 16 in order from the lowest SOH thereof (i.e., from the highest degree of degradation thereof). Consequently, a greater number of the electrically powered lawn mowers 18 belonging to the second group 16 can utilize the batteries. Further, the SOH of the batteries that are moved from the first group 12 to the second group 16 is higher than the required SOH range of the electrically powered lawn mowers 18. Therefore, even if the electrically powered lawn mowers 18 utilize the batteries that are moved from the first group 12 to the second group 16, the performance of the driving time period thereof can be ensured.

In the inventory management system 26 according to the present embodiment, in the case that the required number of batteries for the electrically powered lawn mowers 18 is greater than the number of batteries belonging to the second group 16, the transferring, to the second group 16, of the batteries belonging to the first group 12 as the batteries to be used by the electrically powered taxis 14 is given priority over the transferring of the batteries belonging to another group (for example, the third group 20) to the second group 16 and the supply of the batteries manufactured in the production plant 10 to the second group 16. In accordance with this feature, moving, to the second group 16, of excess inventory of batteries in the first group 12 whose SOH are higher than the required SOH range of the electrically powered lawn mowers 18 is given priority over moving or supplying of the batteries from another process to the second group 16, whereby the excess in the batteries can be utilized efficiently.

In the inventory management system 26 according to the present embodiment, in the case that the required number of batteries for the household electrical power storage devices 22 is greater than the number of batteries belonging to the third group 20, the batteries belonging to the second group 16 as the batteries to be used by the electrically powered lawn mowers 18 are transferred to the third group 20, in order from the lowest SOH thereof (i.e., from the highest degree of degradation thereof). Further, the required number of batteries for the household electrical power storage devices 22 can be satisfied. Consequently, a greater number of the household electrical power storage devices 22 belonging to the third group 20 can utilize the batteries. Further, the SOH of the batteries that are transferred from the second group 16 to the third group 20 is higher than the required SOH range of the household electrical power storage devices 22. Therefore, even if the household electrical power storage devices 22 utilize the batteries that are moved from the second group 16 to the third group 20, the electrical power capacity performance thereof can be ensured. By causing the batteries belonging to the second group 16 to be moved to the third group 20, in order from the lowest SOH thereof (i.e., from the highest degree of degradation thereof), those batteries that shortly cease to satisfy the electrical power capacity of the electrically powered lawn mowers 18 in the second group 16 are preferentially moved to the third group 20, whereby the working efficiency of both of the groups can be maintained.

In the inventory management system 26 according to the present embodiment, after having moved the batteries belonging to the first group 12 as the batteries to be used by the electrically powered taxis 14, to the second group 16, in the case that the required number of batteries required for the electrically powered lawn mowers 18 is greater than the number of batteries belonging to the second group 16, the batteries belonging to the third group 20 as the batteries to be used by the household electrical power storage devices 22 are moved to the second group 16, in order from the highest SOH thereof (i.e., from the lowest degree of degradation thereof). In accordance with this feature, the batteries in the first group 12 and having an SOH higher than the required SOH range of the electrically powered lawn mowers 18 are moved to the second group 16, taking priority over the batteries in the third group 20 which have an SOH lower than the required SOH range of the electrically powered lawn mowers 18. Consequently, from among a larger number of the electrically powered lawn mowers 18 belonging to the second group 16, it is possible to increase the percentage of the number of the electrically powered lawn mowers 18 that are capable of ensuring the performance of the driving time period.

In the inventory management system 26 according to the present embodiment, in the case that the batteries are moved from one group to another group, the batteries are moved within a range of the inventory quantity of the batteries in the one group. In accordance with this feature, in the groups that serve as the movement source of the batteries, the required number of batteries for the respective types of the electrically powered products can be ensured.

### Exemplary Modifications

In the first embodiment, in the case that the required number of batteries for the electrically powered lawn mowers 18 is greater than the number of batteries belonging to the second group 16, then from among the batteries that are stored as inventory in the first group 12, the distribution unit 46 causes the batteries to belong to the second group 16, in order from the lowest SOH thereof (i.e., from the highest degree of degradation thereof). In this instance, in the case that the required number of batteries for the electrically powered lawn mowers 18 is greater than the number of batteries belonging to the second group 16, then from among the batteries belonging to the first group 12, the distribution unit 46 may cause the batteries to belong to the second group 16, in order from the lowest SOH thereof (i.e., from the highest degree of degradation thereof). More specifically, the batteries to be moved from the first group 12 to the second group 16 may be the batteries that are currently being used by the electrically powered taxis 14, regardless of the batteries that are stored as inventory in the first group 12. However, the number of batteries to be moved from the first group 12 to the second group 16 lies within the range of the inventory quantity of the batteries in the first group 12.

Further, in the first embodiment, in the case that the required number of batteries for the electrically powered lawn mowers 18 is greater than the number of batteries belonging to the second group 16, then from among the batteries that are stored as inventory in the third group 20, the distribution unit 46 causes the batteries to belong to the second group 16, in order from the highest SOH thereof (i.e., from the lowest degree of degradation thereof). In this instance, in the case that the required number of batteries for the electrically powered lawn mowers 18 is greater than the number of batteries belonging to the second group 16, then from among the batteries belonging to the third group 20, the distribution unit 46 may cause the batteries to belong to the second group 16, in order from the highest SOH thereof (i.e., from the lowest degree of degradation thereof). More specifically, the batteries to be moved from the third group 20 to the second group 16 may be the batteries that are currently being used by the household electrical power storage devices 22, regardless of the batteries that are stored as inventory in the third group 20. However, the number of batteries to be moved from the third group 20 to the second group 16 lies within the range of the inventory quantity of the batteries in the third group 20.

Further, in the first embodiment, in the case that the required number of batteries for the electrically powered taxis 14 is greater than the number of batteries belonging to the first group 12, then from among the batteries that are stored as inventory in the second group 16, the distribution unit 46 causes the batteries to belong to the first group 12, in order from the highest SOH thereof (i.e., from the lowest degree of degradation thereof). In this instance, in the case that the required number of batteries for the electrically powered taxis 14 is greater than the number of batteries belonging to the first group 12, then from among the batteries belonging to the second group 16, the distribution unit 46 may cause the batteries to belong to the first group 12, in order from the highest SOH thereof (i.e., from the lowest degree of degradation thereof). More specifically, the batteries to be moved from the second group 16 to the first group 12 may be the batteries that are currently being used by the electrically powered lawn mowers 18, regardless of the batteries that are stored as inventory in the second group 16. However, the number of batteries to be moved from the second group 16 to the first group 12 lies within the range of the inventory quantity of the batteries in the second group 16.

Further, in the first embodiment, in the case that the required number of batteries for the household electrical power storage devices 22 is greater than the number of batteries belonging to the third group 20, then from among the batteries that are stored as inventory in the second group 16, the distribution unit 46 causes the batteries to belong to the third group 20, in order from the lowest SOH thereof (i.e., from the highest degree of degradation thereof). In this instance, in the case that the required number of batteries for the household electrical power storage devices 22 is greater than the number of batteries belonging to the third group 20, then from among the batteries belonging to the second group 16, the distribution unit 46 may cause the batteries to belong to the third group 20, in order from the lowest SOH thereof (i.e., from the highest degree of degradation thereof). More specifically, the batteries to be moved from the second group 16 to the third group 20 may be the batteries that are currently being used by the electrically powered lawn mowers 18, regardless of the batteries that are stored as inventory in the second group 16. However, the number of batteries to be moved from the second group 16 to the third group 20 lies within the range of the inventory quantity of the batteries in the second group 16.

[Technical Concepts that can be Obtained from the Embodiments]

A description will be given below concerning the technical concepts that can be grasped from the embodiments described above.

In the inventory management system (26) for the plurality of batteries used by the plurality of types of electrically powered products (14, 18, 22), there are included the degree of degradation range storage unit (40) which stores as the first degree of degradation range the range of the required degree of degradation required for batteries, among the plurality of batteries, that are set in association with the first type of the electrically powered products (14), and stores as the second degree of degradation range the range of the required degree of degradation required for batteries thereamong that are set in association with the second type of the electrically powered products (18), wherein the second degree of degradation range is set to a range in which the degree of degradation is higher than that of the first degree of degradation range, the degree of degradation acquisition unit (36) that acquires the degree of degradation of each of the plurality of batteries, the state of usage storage unit (42) that stores, in association with each other, the types of the electrically powered products and the batteries used by the types of the electrically powered products, and the distribution unit (46) which associates, from among the batteries associated with the first type of the electrically powered products, the batteries having the degree of degradation higher than the first degree of degradation range with the second type of the electrically powered products.

In the above-described inventory management system, the first degree of degradation range and the second degree of degradation range may be set continuously.

In the above-described inventory management system, there may further be included the required number acquisition unit (38) that acquires the required number of batteries for each of the types of the electrically powered products, and the number storage unit (44) in which the number of batteries associated with each of the types of the electrically powered products, and the required number of batteries for each of the types of the electrically powered products are stored in association with each other.

In the above-described inventory management system, the state of usage storage unit may store the degree of degradation of each of the batteries associated respectively with the types of the electrically powered products.

In the above-described inventory management system, in the case that the required number of batteries required for the second type of the electrically powered products is greater than the number of batteries associated with the second type of the electrically powered products, the distribution unit may associate the batteries associated with the first type of the electrically powered products, with the second type of the electrically powered products, in order from the highest degree of degradation of the batteries.

In the above-described inventory management system, in the case that the required number of batteries required for the second type of the electrically powered products is greater than the number of batteries associated with the second type of the electrically powered products, the distribution unit may associate, among the batteries, a battery associated with the first type of the electrically powered products, with the second type of the electrically powered products, by taking priority over the association of the battery associated with the third type of the electrically powered products (22) or the battery manufactured in the production plant (10) with the second type of the electrically powered products.

In the above-described inventory management system, the degree of degradation range storage unit may store, as the third degree of degradation range, the degree of degradation range of the batteries, among the plurality of batteries, that are set in association with the third type of the electrically powered products, wherein the third degree of degradation range may be set to a range in which a degree of degradation is higher than that of the second degree of degradation range, and after having associated, in order from the highest degree of degradation thereof, the batteries associated with the first type of the electrically powered products, with the second type of the electrically powered products, in the case that the required number of batteries required for the second type of the electrically powered products is greater than the number of batteries associated with the second type of the electrically powered products, the distribution unit may associate the batteries associated with the third type of the electrically powered products with the second type of the electrically powered products, in order from the lowest degree of degradation of the batteries.

In the above-described inventory management system, the number storage unit may store, as the inventory quantity, the number of batteries by which the number of batteries associated with each of the types of the electrically powered products is greater than the required number of batteries, and in the case that the required number of batteries required for the second type of the electrically powered products is greater than the number of batteries associated with the second type of the electrically powered products, the distribution unit may associate the batteries associated with the first type of the electrically powered products with the second type of the electrically powered products, in order from the highest degree of degradation of the batteries, and within the range of the inventory quantity of the batteries associated with the first type of the electrically powered products.

In the above-described inventory management system, the degree of degradation may be obtained based on at least one of the SOH (state of health), the number of charging times, or the number of discharging times, of the batteries, and the degree of degradation may become higher as the SOH becomes smaller, higher as the number of charging times becomes higher, and higher as the number of discharging times becomes higher.

### DESCRIPTION OF REFERENCE NUMERALS

14 . . . electrically powered taxis (first electrically powered products)
18 . . . electrically powered lawn mowers (second electrically powered products)
22 . . . household electrical power storage devices (third electrically powered products)
26 . . . inventory management system
36 . . . degree of degradation acquisition unit
38 . . . required number acquisition unit
40 . . . degree of degradation range storage unit
42 . . . state of usage storage unit
44 . . . number storage unit
46 . . . distribution unit

1. An inventory management system for a plurality of batteries used in a plurality of types of electrically powered products, the inventory management system comprising:
a degree of degradation range storage unit configured to store, as a first degree of degradation range, a range of a required degree of degradation required for batteries, among the plurality of batteries, that are set in association with a first type of the electrically powered products, and to store, as a second degree of degradation range, a range of a required degree of degradation required for batteries thereamong that are set in association with a second type of the electrically powered products, wherein the second degree of degradation range is set to a range in which a degree of degradation is higher than a degree of degradation of the first degree of degradation range;
a degree of degradation acquisition unit configured to acquire a degree of degradation of each of the plurality of batteries;
a state of usage storage unit configured to store, in association with each other, the types of the electrically powered products and the batteries used by the types of the electrically powered products; and
a distribution unit configured to associate, from among the batteries associated with the first type of the electrically powered products, a battery having the degree of degradation higher than the first degree of degradation range, with the second type of the electrically powered products.

2. The inventory management system according to claim 1, wherein the first degree of degradation range and the second degree of degradation range are set continuously.

3. The inventory management system according to claim 1, further comprising:
a required number acquisition unit configured to acquire a required number of batteries for each of the types of the electrically powered products; and
a number storage unit configured to store a number of batteries associated with each of the types of the electrically powered products, and the required number of batteries for each of the types of the electrically powered products, in association with each other.

4. The inventory management system according to claim 3, wherein the state of usage storage unit stores the degree of degradation of each of the batteries associated respectively with the types of the electrically powered products.

5. The inventory management system according to claim 4, wherein, in a case that the required number of batteries required for the second type of the electrically powered products is greater than the number of batteries associated with the second type of the electrically powered products, the distribution unit associates the batteries associated with the first type of the electrically powered products, with the second type of the electrically powered products, in order from a highest degree of degradation of the batteries.

6. The inventory management system according to claim 5, wherein, in the case that the required number of batteries required for the second type of the electrically powered products is greater than the number of batteries associated with the second type of the electrically powered products, the distribution unit associates, among the batteries, a battery associated with the first type of the electrically powered products, with the second type of the electrically powered products, by taking priority over associating of a battery associated with a third type of the electrically powered products or a battery manufactured in a production plant with the second type of the electrically powered products.

7. The inventory management system according to claim 5, wherein:
the degree of degradation range storage unit stores, as a third degree of degradation range, a degree of degradation range of batteries, among the plurality of batteries, that are set in association with a third type of the electrically powered products, wherein the third degree of degradation range is set to a range in which a degree of degradation is higher than that of the second degree of degradation range; and
after having associated, in order from the highest degree of degradation of the batteries, the batteries associated with the first type of the electrically powered products, with the second type of the electrically powered products, in the case that the required number of batteries required for the second type of the electrically powered products is greater than the number of batteries associated with the second type of the electrically powered products, the distribution unit associates the batteries associated with the third type of the electrically powered products, with the second type of the electrically powered products, in order as from a lowest degree of degradation of the batteries.

8. The inventory management system according to claim 4, wherein:
the number storage unit stores, as an inventory quantity, a number of batteries by which the number of batteries associated with each of the types of the electrically powered products is greater than the required number of batteries; and
in a case that the required number of batteries required for the second type of the electrically powered products is greater than the number of batteries associated with the second type of the electrically powered products, the distribution unit associates the batteries associated with the first type of the electrically powered products with the second type of the electrically powered products, in order from a highest degree of degradation of the batteries, and within a range of the inventory quantity of the batteries associated with the first type of the electrically powered products.

9. The inventory management system according to claim 1, wherein:
the degree of degradation is obtained based on at least one of a state of health, a number of charging times, or a number of discharging times, of the batteries; and
the degree of degradation becomes higher as the state of health becomes smaller, the degree of degradation becomes higher as the number of charging times becomes higher, and the degree of degradation becomes higher as the number of discharging times becomes higher.
